(19) United States
(12) Patent Application Publication
(10) Pub. No.: US 2014/0244922 A1
(43) Pub. Date: Aug. 28, 2014

(54) MULTI-PURPOSE REGISTER PROGRAMMING VIA PER DRAM ADDRESSABILITY MODE

(71) Applicants: Kuljit S. Bains, Olympia, WA (US); Suneeta Sah, Portland, OR (US)

(72) Inventors: Kuljit S. Bains, Olympia, WA (US); Suneeta Sah, Portland, OR (US)

(21) Appl. No.: 13/997,911

(22) PCT Filed: Jan. 20, 2012
(86) PCT No.: PCT/US2012/021988

§ 371 Date: Jun. 25, 2013

(51) Int. Cl. G11C 7/10

(52) U.S. Cl. CPC G11C 7/1072
USPC 711/105

(57) ABSTRACT

Embodiments of an apparatus, system and method for using Per DRAM Addressability (PDA) to program Multi-Purpose Registers (MPRs) of a dynamic random access memory (DRAM) device are described herein. Embodiments of the invention allow unique 32 bit patterns to be stored for each DRAM device on a rank, thereby enabling data bus training to be done in parallel. Furthermore, embodiments of the invention provide 32 bits of storage per DRAM device on a rank for the system BIOS for storing codes such as MR values, or for any other purpose (e.g., temporary scratch storage to be used by BIOS processes).

### FIELD

Embodiments of the invention generally pertain to computing devices and more particularly to using Per DRAM Addressability (PDA) to program Multi-Purpose Registers (MPRs) of a DRAM device.

### BACKGROUND

Dynamic random access memory (DRAM) devices include Multi-Purpose Registers (MPRs); these registers are programmed by a vendor of the DRAM manufacturer to a specific value and, in the prior art, are not able to be (over) written to other values. What is needed is a process to use existing DRAM logic to program said MPRs, so that processes such as Basic Input/Output System (BIOS) and link training may utilize the MPRs to execute in a more efficient manner.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” are to be understood as describing a particular feature, structure, or characteristic included in at least one implementation of the invention. Thus, phrases such as “in one embodiment” or “in an alternate embodiment” appearing herein describe various embodiments and implementations of the invention, and do not necessarily all refer to the same embodiment. However, they are also not necessarily mutually exclusive.

FIG. 1 is a block diagram of components of a system memory to utilize an embodiment of the invention.

FIG. 2 is a flow diagram of a process for programming Multi-Purpose Registers (MPRs) according to an embodiment of the invention.

FIG. 3A is a timing diagram of a DRAM memory entering Per DRAM Addressability (PDA) mode to program MPRs according to an embodiment of the invention.

FIG. 3B is a timing diagram of a DRAM memory exiting PDA mode according to an embodiment of the invention.

FIG. 4 is a flow diagram of a process for programming MPRs according to an embodiment of the invention.

FIG. 5 is block diagram of a device to utilize an embodiment of the invention.

Descriptions of certain details and implementations follow, including a description of the figures, which may depict some or all of the embodiments described below, as well as discussing other potential embodiments or implementations of the inventive concepts presented herein. An overview of embodiments of the invention is provided below, followed by a more detailed description with reference to the drawings.

### DESCRIPTION

Embodiments of an apparatus, system and method for using Per DRAM Addressability (PDA) to program Multi-Purpose Registers (MPRs) of a dynamic random access memory (DRAM) device are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

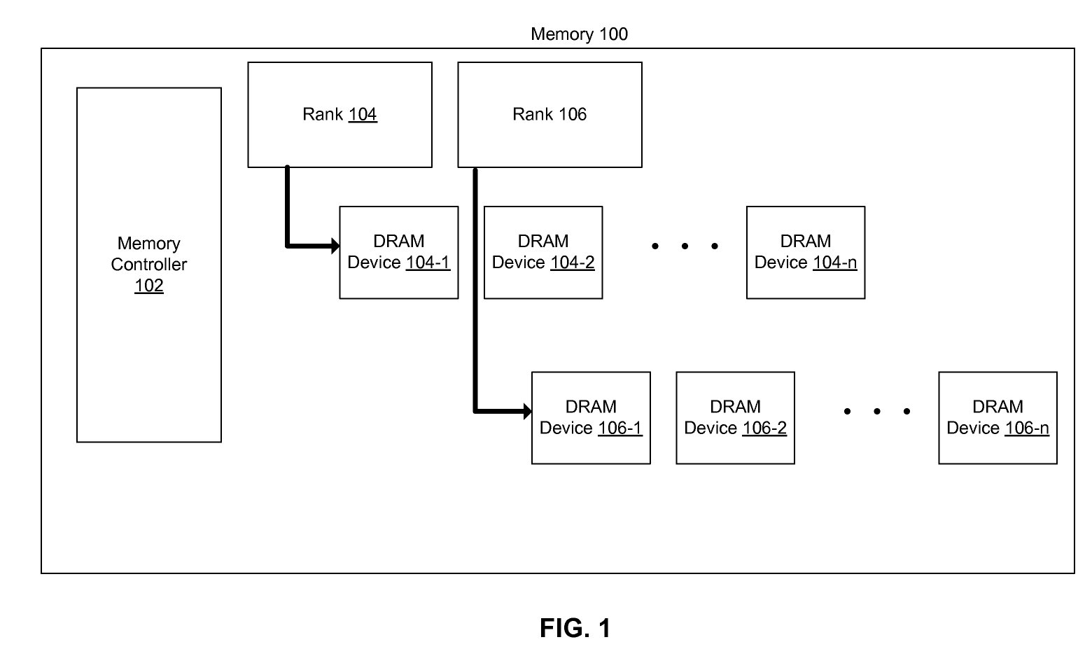

FIG. 1 is a block diagram of components of a system memory to utilize an embodiment of the invention. System memory 100 includes memory controller 102 to control access to memory ranks 104 and 106. In other embodiments, said memory controller is included in a system processor package. Each rank may include a plurality of DRAM devices (e.g., rank 104 includes devices 104-1, 104-2 . . . 104-n; rank 106 includes devices 106-1, 106-2 . . . 106-n).

DRAM devices consistent with the double data rate specification 3 (DDR3, as defined by JEDEC JESD79-3), mode registers are programmed by a memory controller providing a Mode Register Set (MRS) command with valid bank addresses. Said memory controller further asserts chip select low and applicable data on the address inputs—e.g., bank address bits BA[3:0], are used to select individual mode registers within the DRAM; address bits A[15:0] are used as operands for actual register content to be programmed. The above process is limited in that all mode registers of a rank are programmed with the same data (e.g., if system memory 100 were consist with DDR3, all mode registers of DRAM devices 104-1 to 104-n of rank 104 would be programmed to have the same value, and so on).

Proposed DDR4 specifications would instead allow DRAM devices to be uniquely programmed by the host system by utilizing strobes and data I/O lines (e.g., DQ[0]) of each DRAM. Uniquely programming DRAM devices of a rank is herein referred to as Per DRAM Addressability (PDA).

A PDA process may include operations to place the DRAM in PDA mode (i.e., similar to the DDR3 MRS functionality described above) and program unique DRAM devices by using MRS commands, address inputs, and DQ[0]. As system memory 100 is consistent with proposed DDR4 specifications, PDA may be used, for example, to program different On-Die Termination (ODT) or Vref values on DRAM devices on a given rank (e.g., devices 104-1, 104-2 . . . 104-n of rank 104; devices 106-1, 106-2 . . . 106-n of rank 106).

In this embodiment of the invention, each of the DRAM devices in ranks 104 and 106 include four 8-bit programmable Multi-Purpose Registers (MPRs) used for DQ bit pattern storage. DRAM devices consistent with proposed DDR4 specifications include four pages of MPR registers. In some embodiments, page 0 includes four 8-bit programmable MPRs used for DQ bit pattern storage.

In embodiments of the invention, said MPRs are programmed using the command/address (C/A) bus. These registers, once programmed, are accessed with read commands to drive the MPR bits on to the DQ bus during link training The training program is typically a software program stored in a basic input/output system (BIOS) memory device, but it may also be implemented within the device hardware. The training program executes an algorithm, which determines appropriate timing delays associated with each memory interface signal.

In embodiments of the invention, MPR mode enable and page selection is done via MR commands as shown in Table 1 below:

TABLE 1
MR3

| Address | Operating Mode | Description |
|---|---|---|
| A2 | MPR operation | 0 = Normal |
| | | 1 = Dataflow from/to |
| | | MPR |
| A1:A0 | MPR selection | 00 = page 0 |
| | | 01 = page 1 |
| | | 10 = page 2 |
| | | 11 = page 3 |

In embodiments of the invention, page 0 is for both read and write, while pages 1-3 are read-only. Any MPR location (i.e., MPR0-MPR3) in page 0 may be read through any of three readout modes (i.e., serial, parallel or staggered); pages 1, 2, 3 support serial readout mode.

After power-up, the content of MPR page 0 may include default values as defined in Table 2. MPR page 0 is writable when an MPR write command is issued by memory controller 102. In some embodiments, DRAM devices 104-1, 104-2 . . . 104-n of rank 104 and DRAM devices 106-1, 106-2 . . . 106-n of rank 106 keep the default values below unless an MPR write command is issued.

TABLE 2
MPR page 0 (training pattern)

| | | rd/wr default value |
|---|---|---|
| Address | MPR Location | (8 bits) |
| BA1:BA0 | 00 = MPR0 | 0101 0101 |
| BA1:BA0 | 01 = MPR1 | 0011 0011 |
| BA1:BA0 | 10 = MPR2 | 0000 1111 |
| BA1:BA0 | 11 = MPR3 | 0000 0000 |

As described below, embodiments of the invention allow unique 32 bit patterns to be stored for each DRAM device on a rank, enabling data bus training to be done in parallel. Furthermore, embodiments of the invention provide 32 bits of storage per DRAM device on a rank for the system BIOS for storing codes such as MR values, or for any other purpose (e.g., temporary scratch storage to be used by BIOS processes).

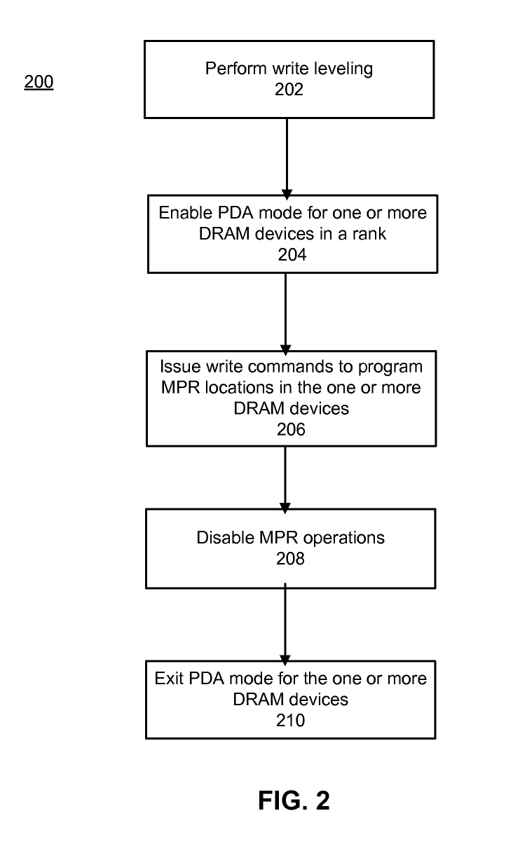

FIG. 2 is a flow diagram of a process for programming MPRs according to an embodiment of the invention. Flow diagrams as illustrated herein provide examples of sequences of various process actions. Although shown in a particular sequence or order, unless otherwise specified, the order of the actions can be modified. Thus, the illustrated implementations should be understood only as examples, and the illustrated processes can be performed in a different order, and some actions may be performed in parallel. Additionally, one or more actions can be omitted in various embodiments of the invention; thus, not all actions are required in every implementation. Other process flows are possible.

Process 200 includes operations for performing write leveling operations on system DRAM memory, 202. Write leveling operations comprise a write test which tests the ability of the memory system to accurately write information (e.g., de-skew and match the timing of the DQ strobe (DQS) to clock relationship).

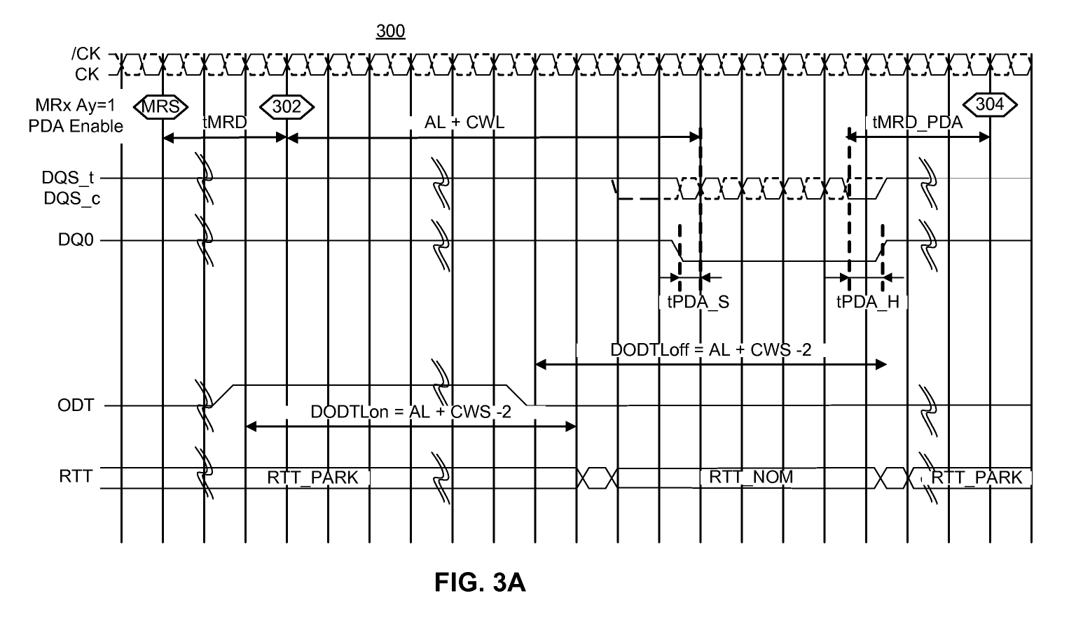

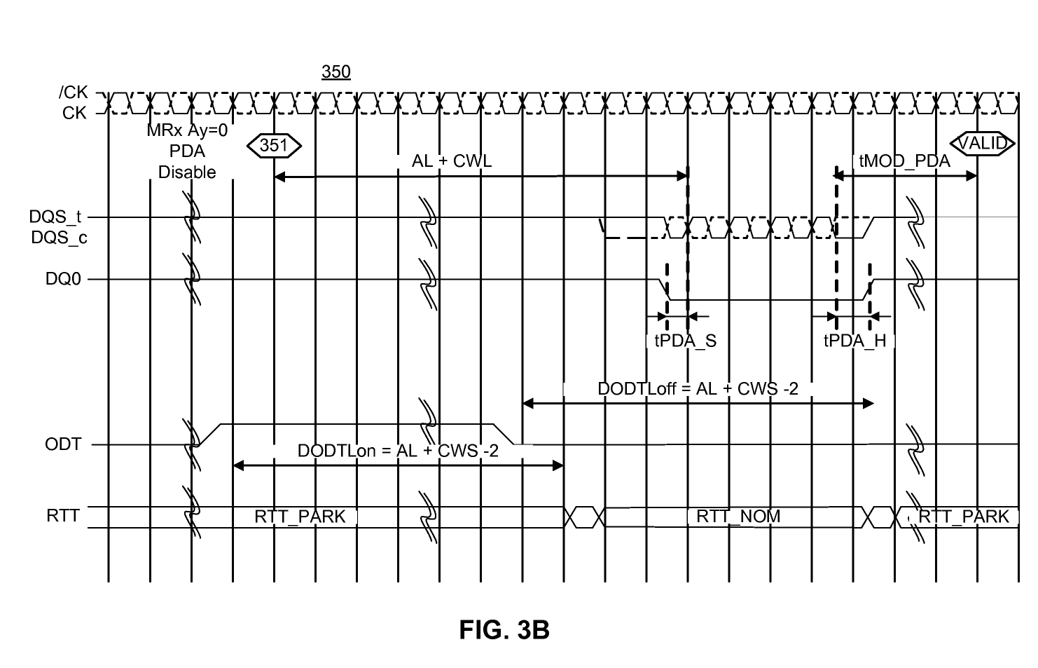

PDA is enabled for DRAM devices on a rank, 204. In some embodiments, PDA mode is enabled using MR[x] address bit “A[y]=1b” (e.g., MR3 bit “A4=1b”). This is an MRS command that is permitted in PDA mode with DQ=0 sent to devices that are to be programmed using the MPR command. In PDA mode, all MRS commands are qualified with DQ0. DRAM devices capture DQ0 by using the DataQ strobe signal (DQS_c) and the DataQ test strobe signal (DQS_t) as shown in FIGS. 3A-3B and described below. If the value of DQ0 is 0, then DRAM executes the MRS command; if the value on DQ0 is 1, then the DRAM ignores the MRS command. The controller may be used to drive all DQ bits.

Write commands are issued to program MPR locations in page 0, 206. Bank address bits BA1 and BA0 indicate MPR location and address bits A[7:0] comprise the content for the specified MPR location. In some embodiments, only MRS commands are permitted during PDA mode.

MPR operations are disabled after said write command are issued, 208, by programming MR3 address bit to “A2=1b.” This is an MRS command, and DQ0 may be set to 0 for devices that were placed in MPR operation in operation 204. PDA mode is exited, 210, by setting MR[x] address bit “A[y]=0b” (e.g., MR3 bit “A4=0b”).

FIG. 3A is a timing diagram of a DRAM memory entering PDA mode to program MPRs according to an embodiment of the invention. Diagram 300 illustrates timing for various signals within a DRAM memory device. In diagram 300, PDA mode is enabled by setting MRx bit “A[y]=1b” (e.g., MR3 bit “A4=1b”).

In PDA mode, all MRS commands are qualified with DQ0. DRAM devices capture DQ0 by using the DataQ strobe signal (DQS_c) and the DataQ test strobe signal (DQS_t) as shown in diagram 300.

In this diagram, the mode register set command cycle time at PDA mode is shown to be comprised of Additive Latency (AL) (i.e., internal delay); Column Address Strobe Write Latency (CWL), which indicates the number of clock cycles between the registration of a write command and the availability of the first bit of data; and mode register set command cycle time for the PDA (tMRD_PDA). Thus, the minimum time between two MRS commands (shown as MRS commands 302 and 304) is AL+CWL+3.5 CK cycles+tMRD_PDA.

For DDR3, Dynamic ODT (RTT_WR) allows the DRAM to change ODT values during a WRITE command without an MRS command. Diagram 300, however, is a timing diagram for a DRAM consistent with proposed DDR4 specification, and illustrates the following Mode Register Settings:

RTT_PARK MR 5 {A8:A6}=Enable

RTT_NOM MR 1 {A9:A6:A2}=Enable

During RTT_NOM, data termination is controlled by the ODT signal, and the timing parameters described in Table 3 below. During system operation as shown in timing diagram 300, the first ODT value (RTT_PARK) is applied to target devices when the ODT signal is inactive or in de-asserted state; The second ODT value (RTT_NOM) is applied only to the non-target ranks when the ODT signal is asserted.

TABLE 3

| Symbol | Parameter |
|---|---|
| DODTLon | Direct ODT turn on latency |
| DODTLoff | Direct ODT turn off latency |
| tADC | RTT change timing skew |
| tAONAS | Asynchronous RTT_NOM turn-on delay |
| tAONFAS | Asynchronous RTT_NOM turn-off delay |

FIG. 3B is a timing diagram of a DRAM memory exiting PDA mode to program MPRs according to an embodiment of the invention. Diagram 350 illustrates timing for various signals within a DRAM memory device. In diagram 350, the DRAM is removed from PDA mode by setting MRx bit “Ay=0b” (e.g., MR3 bit “A4=0b”); said command is shown in the diagram as command 351 and with DQ0=0 (after a delay of AL+CWL).

Removing a DRAM from per DRAM addressability mode may require programming the entire MR3 when the MRS command is issued. This may impact some per DRAM values programmed within a rank as the exit command is sent to the rank. In order to avoid such a case, in some embodiments said ‘Ay’ bit (e.g., ‘A4’) is located in a mode register that does not have any ‘per DRAM addressability’ mode controls.

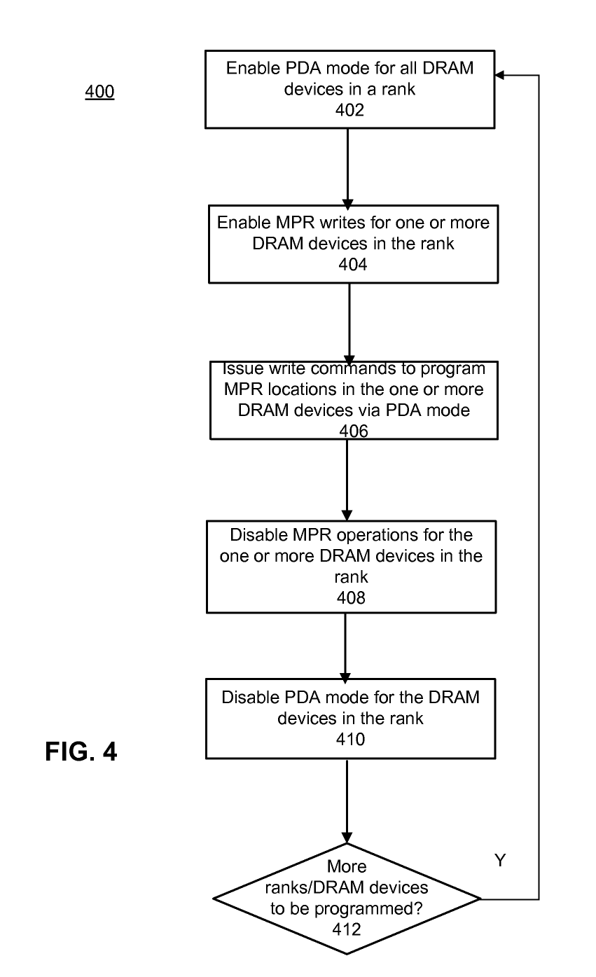

FIG. 4 is a flow diagram of a process for programming MPRs according to an embodiment of the invention. Process 400 includes operations for enabling PDA mode for all DRAM devices in a rank, 402. MPR page 0 operation mode is enabled (i.e., using MR3 A2=1 and A1:A0=00 (page 0), as described above), 404. In some embodiments, because all DRAM devices in the rank are in PDA mode, selective enabling of MPR for the DRAM devices may be executed; in other embodiments, all DRAM devices are enabled for MPR and the control of write data may be done when MPR writes are issued. Write commands are issued to program MPR locations in page 0, 406 (i.e., bank address bits BA1 and BA0 indicate MPR location and address bits A[7:0] comprise the content for the specified MPR location).

MPR operations are disabled after said write commands are issued, 408, by programming MR3 address bit to “A2=1b.” PDA mode is disabled for the DRAM devices in the rank, 410. If other DRAM devices in the rank are to be programmed, 412, process 400 is repeated.

Thus, process 400 ensures that only MRS commands are sent during PDA mode. The write commands for MPR programming goes to all devices on a rank. The MPR programming takes place for devices that are in MPR mode. Devices that are not in MPR mode still receive said write command from operation 406, but with no data following the command because the MPR pages are still closed, thus the DRAM ignores the write command.

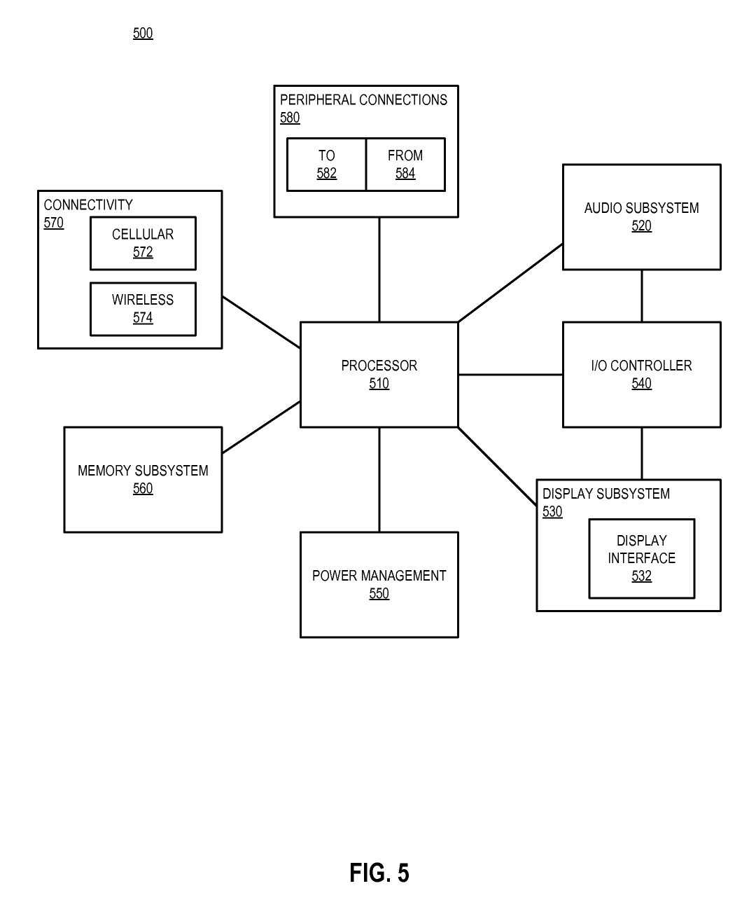

FIG. 5 is block diagram of a device to utilize an embodiment of the invention. Computing device 500 represents a mobile computing device, such as a computing tablet, a mobile phone or smartphone, a wireless-enabled e-reader, or other wireless mobile device. It will be understood that certain of the components are shown generally, and not all components of such a device are shown in device 500.

Device 500 includes processor 510, which performs the primary processing operations of device 500. Processor 510 can include one or more physical devices, such as microprocessors, application processors, microcontrollers, programmable logic devices, processor cores, or other processing means. The processing operations performed by processor 510 include the execution of an operating platform or operating system on which applications and/or device functions are executed. The processing operations include operations related to I/O (input/output) with a human user or with other devices, operations related to power management, and/or operations related to connecting device 500 to another device. The processing operations may also include operations related to audio I/O and/or display I/O.

In one embodiment, device 500 includes audio subsystem 520, which represents hardware (e.g., audio hardware and audio circuits) and software (e.g., drivers, codecs) components associated with providing audio functions to the computing device. Audio functions can include speaker and/or headphone output, as well as microphone input via any of the audio jacks described above. Devices for such functions can be integrated into device 500, or connected to device 500. In one embodiment, a user interacts with device 500 by providing audio commands that are received and processed by processor 510.

Display subsystem 530 represents hardware (e.g., display devices) and software (e.g., drivers) components that provide a visual and/or tactile display for a user to interact with the computing device. Display subsystem 530 includes display interface 532, which includes the particular screen or hardware device used to provide a display to a user. In one embodiment, display interface 532 includes logic separate from processor 510 to perform at least some processing related to the display. In one embodiment, display subsystem 530 includes a touchscreen device that provides both output and input to a user.

I/O controller 540 represents hardware devices and software components related to interaction with a user. I/O controller 540 can operate to manage hardware that is part of audio subsystem 520 and/or display subsystem 530. Additionally, I/O controller 540 illustrates a connection point for additional devices that connect to device 500 through which a user might interact with the system. For example, devices that can be attached to device 500 might include microphone devices, speaker or stereo systems, video systems or other display device, keyboard or keypad devices, or other I/O devices for use with specific applications such as card readers or other devices.

As mentioned above, I/O controller 540 can interact with audio subsystem 520 and/or display subsystem 530. For example, input through a microphone or other audio device can provide input or commands for one or more applications or functions of device 500. Additionally, audio output can be provided instead of or in addition to display output. In another example, if display subsystem includes a touchscreen, the display device also acts as an input device, which can be at least partially managed by I/O controller 540. There can also be additional buttons or switches on device 500 to provide I/O functions managed by I/O controller 540.

In one embodiment, I/O controller 540 manages devices such as accelerometers, cameras, light sensors or other environmental sensors, or other hardware that can be included in device 500. The input can be part of direct user interaction, as well as providing environmental input to the system to influence its operations (such as filtering for noise, adjusting displays for brightness detection, applying a flash for a camera, or other features).

Memory subsystem 560 includes memory devices for storing information in device 500. Memory can include nonvolatile (state does not change if power to the memory device is interrupted) and/or volatile (state is indeterminate if power to the memory device is interrupted) memory devices. Memory 560 can store application data, user data, music, photos, documents, or other data, as well as system data (whether long-term or temporary) related to the execution of the applications and functions of system 500. Said memory devices are capable of having MPRs across a DRAM rank to have different values via PDA mode programming as described above.

Connectivity 570 includes hardware devices (e.g., wireless and/or wired connectors and communication hardware) and software components (e.g., drivers, protocol stacks) to enable device 500 to communicate with external devices. The device could be separate devices, such as other computing devices, wireless access points or base stations, as well as peripherals such as headsets, printers, or other devices.

Connectivity 570 can include multiple different types of connectivity. To generalize, device 500 is illustrated with cellular connectivity 572 and wireless connectivity 574. Cellular connectivity 572 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity 574 refers to wireless connectivity that is not cellular, and can include personal area networks (such as Bluetooth), local area networks (such as WiFi), and/or wide area networks (such as WiMax), or other wireless communication.

Peripheral connections 580 include hardware interfaces and connectors, as well as software components (e.g., drivers, protocol stacks) to make peripheral connections. It will be understood that device 500 could both be a peripheral device (“to” 582) to other computing devices, as well as have peripheral devices (“from” 584) connected to it. Device 500 commonly has a “docking” connector to connect to other computing devices for purposes such as managing (e.g., downloading and/or uploading, changing, synchronizing) content on device 500. Additionally, a docking connector can allow device 500 to connect to certain peripherals that allow device 500 to control content output, for example, to audiovisual or other systems.

In addition to a proprietary docking connector or other proprietary connection hardware, device 500 can make peripheral connections 580 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other type.

Various components referred to above as processes, servers, or tools described herein may be a means for performing the functions described. Each component described herein includes software or hardware, or a combination of these. Each and all components may be implemented as software modules, hardware modules, special-purpose hardware (e.g., application specific hardware, ASICs, DSPs, etc.), embedded controllers, hardwired circuitry, hardware logic, etc. Software content (e.g., data, instructions, configuration) may be provided via an article of manufacture including a non-transitory, tangible computer or machine readable storage medium, which provides content that represents instructions that can be executed. The content may result in a computer performing various functions/operations described herein.

A computer readable non-transitory storage medium includes any mechanism that provides (i.e., stores and/or transmits) information in a form accessible by a computer (e.g., computing device, electronic system, etc.), such as recordable/non-recordable media (e.g., read only memory (ROM), random access memory (RAM), magnetic disk storage media, optical storage media, flash memory devices, etc.). The content may be directly executable (“object” or “executable” form), source code, or difference code (“delta” or “patch” code). A computer readable non-transitory storage medium may also include a storage or database from which content can be downloaded. Said computer readable medium may also include a device or product having content stored thereon at a time of sale or delivery. Thus, delivering a device with stored content, or offering content for download over a communication medium may be understood as providing an article of manufacture with such content described herein.

1. A method comprising:
enabling a per DRAM addressability (PDA) mode for programming one or more dynamic random access memory (DRAM) devices in a rank;
enabling a multi-purpose register (MPR) programming mode for the one or more DRAM devices and
for each of the one or more DRAM devices, writing data to a multi-purpose register (MPR).

2. The method of claim 1, wherein the MPR programming mode is enabled for a plurality of DRAM devices, and the data written to the MPRs for each DRAM device comprises different values.

3. The method of claim 2, wherein the data written to the MPRs comprises DRAM write training data, and the method further comprises:
executing a write training process for the DRAM devices in parallel.

4. The method of claim 1, further comprising:
receiving the data to be written to the MPR from a Basic Input/Output System (BIOS).

5. The method of claim 1, further comprising:
enabling PDA mode for all DRAM devices in the rank.

6. The method of claim 1, further comprising:
receive data on a command/address (C/A) bus for writing data to the MPR.

7. A system comprising:
a processing core;
a memory including a dynamic random access memory (DRAM) rank having a plurality of DRAM devices;
an antenna to receive data to be stored in the memory; and
a memory controller to:
enable a per DRAM addressability (PDA) mode for programming one or more of the DRAM devices;
enable a multi-purpose register (MPR) programming mode for the one or more DRAM devices; and
for each of the one or more DRAM devices, write data to a multi-purpose register (MPR).

8. The system of claim 7, wherein the MPR programming mode is enabled for a plurality of DRAM devices, and the data written to the MPRs for each DRAM device comprises different values.

9. The system of claim 8, wherein the data written to the MPRs comprises DRAM write training data, and the memory controller to further:
execute a write training process for the DRAM devices in parallel.

10. The system of claim 7, the memory controller to further:
receive the data to be written to the MPR from a Basic Input/Output System (BIOS).

11. The system of claim 7, the memory controller to further:
enable PDA mode for all DRAM devices in the rank.

12. The system of claim 7, the memory controller to further:
receive data on a command/address (C/A) bus for writing data to the MPR.

13. An apparatus comprising:
a dynamic random access memory (DRAM) rank including a plurality of DRAM devices; and
logic to:
enable a per DRAM addressability (PDA) mode for programming one or more DRAM devices;
enable a multi-purpose register (MPR) programming mode for the one or more DRAM devices; and
for each of the one or more DRAM devices, write data to a multi-purpose register (MPR).

14. The apparatus of claim 13, wherein the MPR programming mode is enabled for a plurality of DRAM devices, and the data written to the MPRs for each DRAM device comprises different values.

15. The apparatus of claim 14, wherein the data written to the MPRs comprises DRAM write training data, and the logic to further:
execute a write training process for the DRAM devices in parallel.

16. The apparatus of claim 13, the logic to further:
receive the data to be written to the MPR from a Basic Input/Output System (BIOS).

17. The apparatus of claim 13, the logic to further:
enable PDA mode for all DRAM devices in the rank.

18. The apparatus of claim 13, the logic to further:
receive data on a command/address (C/A) bus for writing data to the MPR.
